(19) United States
(12) Patent Application Publication
(10) Pub. No.: US 2009/0162970 A1
(43) Pub. Date: Jun. 25, 2009

(54) MATERIAL MODIFICATION IN SOLAR CELL FABRICATION WITH ION DOPING

(76) Inventor: Michael X. Yang, Palo Alto, CA (US)

Correspondence Address: Scott Faber, Esq.;Varian Semiconductor Equipment Associates, Inc, 35 Dory Road, Gloucester, MA, 01930, US

(21) Appl. No.: 11/961,126

(22) Filed: Dec. 20, 2007

(51) Int. Cl. H01L 31/0368; H01L 31/0376

(52) U.S. Cl. 438/96; 438/97; 257/E31.048; 257/E31.045

(57) ABSTRACT

An approach for material modification in solar cell fabrication with ion doping is described. In one embodiment, there is a method of forming a thin-film solar cell. In this embodiment, a substrate is provided and a thin-film layer is deposited on the substrate. The thin-film solar cell layer is exposed to an ion flux to passivate a defect.

### BACKGROUND

This disclosure relates generally to solar cell fabrication, and more specifically to making modifications to thin-film solar cell material during fabrication.

Several materials have been used in the conversion of photon energy into electricity, including silicon (Si), silicon germanium (SiGe), group III-V element materials (e.g., gallium arsenide (GaAs), indium phosphide (InP), etc.), chalcogenide (copper indium gallium selenide (CIGS), cadium telluride (CdTe), etc.), photochemical (dye sensitized) and organic polymers (fullerene derivatives, etc.).

These materials have been used to form solar cells which can take on several structures. In general, commercial solar cells can be categorized into crystalline solar cells (silicon, GaAs) and thin-film solar cells (amorphous Si, microcrystalline silicon, CIGS, CdTe, etc.). Thin-film solar cell structures can be fabricated on different substrates, including glass (rigid) and stainless steel sheets (flexible). Mainstream crystalline silicon solar cells have cell efficiencies between 14% and 22%. In comparison, commercially available single junction thin-film solar cells have an efficiency only between 6% and 13%.

Efficiencies of thin-film solar cells are lower compared to silicon wafer-based solar cells (e.g., bulk material of crystalline silicon), but manufacturing costs associated with fabricating thin-film solar cells can be also lower, making it possible to achieve a lower cost per watt with thin-film solar cells as compared to the silicon wafer-based solar cells. Despite the lower cost per watt associated with thin-film solar cells, increasing the energy conversion efficiency of thin-film solar cells is desirable to further drive down solar electricity cost. Currently, single junction thin-film silicon solar cells have only an efficiency of 6% to 10%, in contrast of 14% to 22% of crystalline silicon wafer solar cells. The reduced energy conversion efficiency associated with thin-film silicon solar cells is presumably due to the amorphous nature and high defect density in the thin-film silicon solar cells. In addition, the thin-film silicon solar cells suffer from light-induced metastability that increases the density of dangling-bond defects by one to two orders of magnitude which results in a reduction in carrier lifetime and photoconductivity in the films of the thin-film silicon solar cells.

### SUMMARY

In a first embodiment, there is a method of forming a thin-film solar cell. In this embodiment, the method comprises providing a substrate; depositing a thin-film layer on the substrate; and exposing the thin-film layer to an ion flux to passivate a defect.

In a second embodiment, there is a method of forming a thin-film solar cell. In this embodiment, the method comprises providing a substrate; depositing a thin-film silicon layer on the substrate; exposing the thin-film silicon layer to a light source; and implanting the thin-film silicon layer with an ion flux to passivate defects.

In a third embodiment, there is a method of forming a thin-film solar cell. In this embodiment, the method comprises providing a substrate; depositing a thin-film silicon layer on the substrate; exposing the thin-film silicon layer to a light source; and implanting the thin-film silicon layer with an ion flux to passivate a defect, wherein the implanting of the thin-film silicon layer with an ion flux occurs at a temperature that is less than about 300° C. and wherein the ion flux contains ions selected from the group consisting of hydrogen, and deuterium; and capping the thin film silicon layer with a conductive material.

### BRIEF DESCRIPTION OF THE DRAWINGS

FIG. 1 shows a flow chart describing a method of forming a thin-film solar cell using aspects according to one embodiment of this disclosure;

FIG. 2 shows a schematic block diagram of an ion implanter used in the forming of a thin-film solar cell according to one embodiment of this disclosure;

FIG. 3 shows a schematic block diagram of a plasma processing tool used in the forming of a thin-film solar cell according to one embodiment of this disclosure; and

FIG. 4 is a cross-sectional diagram of a thin-film solar cell fabricated according to one embodiment of this disclosure.

### DETAILED DESCRIPTION

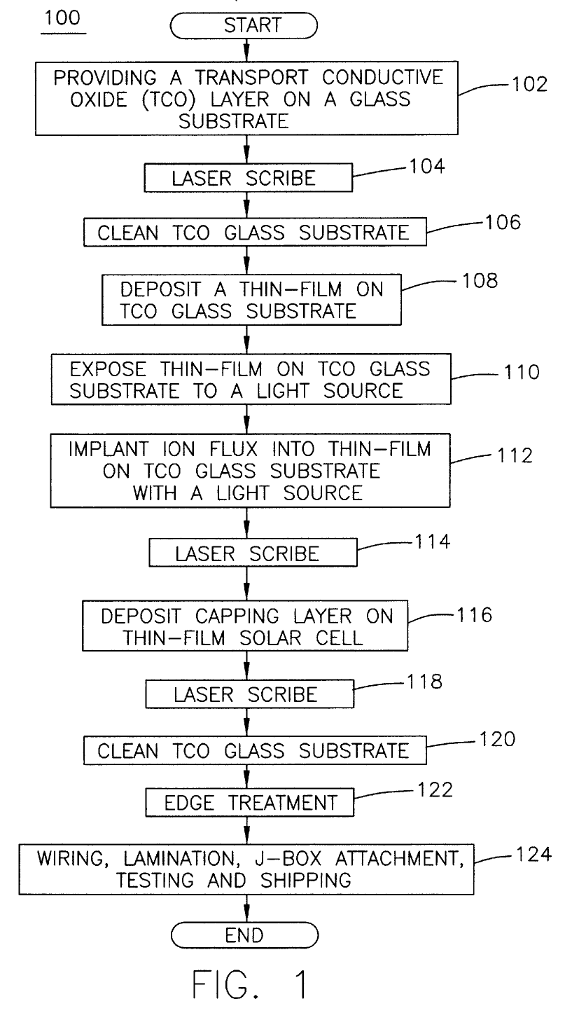

FIG. 1 shows a flow chart describing a method 100 of forming a thin-film solar cell using aspects according to one embodiment of this disclosure. The method 100 of FIG. 1 begins at 102 where a transport conductive oxide (TCO) layer on a glass substrate is provided. In one embodiment, the TCO layer may be fluorine (F) or antimony doped tin oxide (Sb doped with SnO₂). Those skilled in the art will recognize that other materials such as indium tin oxide (ITO) and zinc oxide (ZnO) can be used in place of or in combination with the TCO. Furthermore, it is possible that the TCO layer could be deposited on a substrate different than glass such as stainless steel or any other flexible substrate.

After providing the TCO layer on a glass substrate, a laser scribe is performed at 104. The laser scribe is performed by a laser scribe tool which scans a laser spot/beam across the samples with precision automation control and enables construction of individual solar cell structures.

After a cleaning of the TCO glass substrate at 106, a silicon thin-film is deposited on the TCO glass substrate at 108. In one embodiment, the thin-film silicon solar cell includes a p-i-n silicon layer deposition. For a typical p-i-n silicon solar cell deposition, an i layer of silicon is deposited on a p layer of silicon, followed by a deposition of an n layer of silicon on the i layer of silicon. The p-i-n silicon layer forms a photon-absorption layer in the thin-film silicon solar cell structure. In general, the p-i-n silicon films are formed by and deposited on the TCO glass substrate by using a plasma-enhanced chemical vapor deposition (PECVD) system. Typical conditions for depositing the thin-film solar cell on a soda lime glass substrate include film deposition at a substrate temperature of about 200° C. to about 250° C. Deposition temperature can be significantly higher on other substrates, including other types of glasses, stainless steel, etc. Those skilled in the art will recognize that other types of thin-film silicon can be used such as a multi-junction amorphous/microcrystalline silicon or thin film silicon fabricated by liquid phase epitaxy (LPE) or other techniques.

As mentioned above, most thin-film silicon solar cells suffer from light-induced metastability that increases the density of dangling-bond defects by one to two orders of magnitude which results in a reduction in carrier lifetime and photoconductivity in the films of the thin-film solar cells. It is generally believed that the light-induced metastability that increases the density of dangling-bond defects is due to dissociation of silicon-hydrogen (Si:H) bonds that are formed during PECVD deposition of amorphous/microcrystalline silicon. The light-induced dissociation of a-Si:H (amorphous silicon hydrogen) bond results in the reduction of the carrier lifetime and photoconductivity and thus is detrimental to the performance of the thin-film silicon solar cell.

This disclosure provides an approach that overcomes some of the drawbacks associated with dissociation of a-Si:H bond under light exposure in typical thin-film silicon solar cells. In particular, embodiments of this disclosure are directed to using ion implantation to implant ions such as hydrogen or deuterium ions into the thin-film solar cell to passivate the defect sites in the silicon film and thus lower the overall defect level in the solar cells, thus improving the energy conversion efficiency associated with thin-film solar cells.

Referring back to FIG. 1, the thin-film silicon on TCO glass substrate is exposed to a light source at 110. In this optional step, light from a light source such as a simulated sunlight source, an ultraviolet lamp and a laser exposes the thin-film silicon and aids in the passivation of the Si:H bonds by inducing dissociation of metastable Si—H bonds and preparing defect sites prior to effective hydrogen passivation which is discussed below with more details.

Complementing the light exposure of 110 or in place thereof, processing block 112 which designates the ion implantation of an ion flux into the thin-film, aids in the reduction in the defects in the thin-film silicon film. Ion implantation of the ion flux can occur via an ion implanter, a plasma processing tool or an electrolyte solution. Below are more details of an ion implanter and a plasma processing tool that can be used to implant the ion flux into the thin-film silicon. With regard to the use of the electrolyte solution, it is well known that an ion flux can be generated in a liquid phase (e.g., in an electrolyte solution with a voltage bias) so a separate description is not provided.

The ion flux can be one or more of a variety of different ions. For instance the ion flux can be ions selected from the group consisting of boron, phosphorous, hydrogen, and deuterium. The implanting of boron and phosphorous ions aid in improving the quality of the solar cell junction by passivation of defect sites as well as possible improvement of n- and p-layer conductivity and improvement of junction profiles in an n-/i-/p-silicon film stack in the solar cell structure. With precise control of ion energy, boron and phosphorus ions can be implanted into p- and n-layers in the thin film silicon solar cell structure, independently. The implanting of the hydrogen and deuterium aids in the hydrogen passivation of defect sites in an entire p-/i-/n-silicon film stack. With a control of voltage ramp in ion implantation or plasma doping tool, hydrogen and deuterium ions can be implanted with desirable depth profile control, including a uniform depth profile across the entire p-/i-/n-silicon film stack.

Bonding energy is significantly stronger for silicon-deuterium bonds comparing with silicon-hydrogen bonds. An effective deuterium passivation of defect sites in thin film silicon solar cell can make solar cell performance more stable, upon subsequent/additional light exposure.

The use of an ion implanter and a plasma implantation tool is beneficial in effective solar cell defect site passivation and solar cell junction quality improvement because of the unique control features that the ion implanter and plasma implantation tools provide. In particular, use of an ion implanter and a plasma implantation tool enables a precise adjustment of dopant level, dopant depth profile and junction transition quality by ion dosage, ion energy and angular control if necessary.

Because the thin-film solar cell of this disclosure is described as including a glass substrate, it is necessary that defect passivation occurs at a temperature that is less than melting temperature of the glass substrate, which is approximately 300° C. for soda lime architecture glass. It is significantly lower than the temperature limit for crystalline silicon solar cell manufacturing which exceeds 1000° C. At a temperature less than 300° C., hydrogen diffusivity in silicon is low. A traditional hydrogen passivation technique including gaseous hydrogen (H₂) and impingement of atomic or molecular hydrogen ions (H+/H₂⁺) by a PECVD tool will not be very effective since they can only provide hydrogen to the surface of the silicon film but cannot effectively passivate the defects in the bulk of silicon film. As a result, an effective hydrogen passivation of a thin film silicon solar cell needs to be carried out with direct ion implant with an ion implanter or plasma implantation tool.

Referring back to FIG. 1, after the ion implantation, a laser scribe is performed at 114. The laser scribe enables front and back of adjacent cells of the thin-film solar cell to inter-connect in series.

At 116, a capping layer is deposited on the thin-film solar cell. The capping layer serves as a top electrode for the solar cell. In one embodiment, the capping layer includes a layer of zinc oxide (ZnO) deposited on a layer of aluminum (Al). Those skilled in the art will recognize that other material can be used for the capping layer such as a layer of ZnO deposited on a layer of silver (Ag). In one embodiment, the capping layer is deposited on the thin-film solar cell by using a physical vapor deposition (PVD).

After depositing the capping layer, a laser scribe is performed at 118. The laser scribe at this point is performed to complete the final circuitry of the solar cell connections, to make sure each isolated solar cell (as defined by previous laser scribe processes) is connected in series.

The thin-film solar cell is then cleaned at 120, prior to module assembly steps. At 122, the thin-film solar cell is cut, edge-treated and isolated (collectively referred to as edge treatment). Finally, at 124, wiring, lamination, attachment, testing and shipping are performed.

The foregoing flow chart shows some of the processing functions associated with fabricating a thin-film solar cell with improved energy conversion efficiency. In this regard, each block represents a process act associated with performing these functions. It should also be noted that in some alternative implementations, the acts noted in the blocks may occur out of the order noted in the figure or, for example, may in fact be executed in different order, depending upon the act involved. Also, one of ordinary skill in the art will recognize that additional blocks that describe the processing functions may be added. For example, PECVD of the silicon thin film on the TCO glass substrate may use a variation to the typical hydrogen and silane materials. In one embodiment, the PECVD can be used with deuterium in place of hydrogen atoms in both hydrogen and silane or in another embodiment, deuterium can be used to replace hydrogen in either hydrogen or silane. PECVD of silicon is usually carried out with a gas mixture of hydrogen (H₂) and silane (SiH₄) molecules. Hydrogen atoms in both hydrogen and silane precursors can be sources to residual hydrogen in the deposited thin film silicon layer. By replacement of hydrogen by deuterium in either hydrogen or silane molecules, or replacement of hydrogen by deuterium in both hydrogen and silane molecules, deuterium instead of hydrogen will be present in the deposited thin film silicon layer. Due to a stronger silicon-deuterium bond energy with reference to silicon-hydrogen bond, less silicon-deuterium bond dissociation will take place upon light radiation, which can result in more stable solar cell efficiency. In another embodiment, the PECVD can use materials selected from the group consisting of hydrogen and silane, deuterium and deuterated silane, deuterium and silane, and hydrogen and deuterated silane.

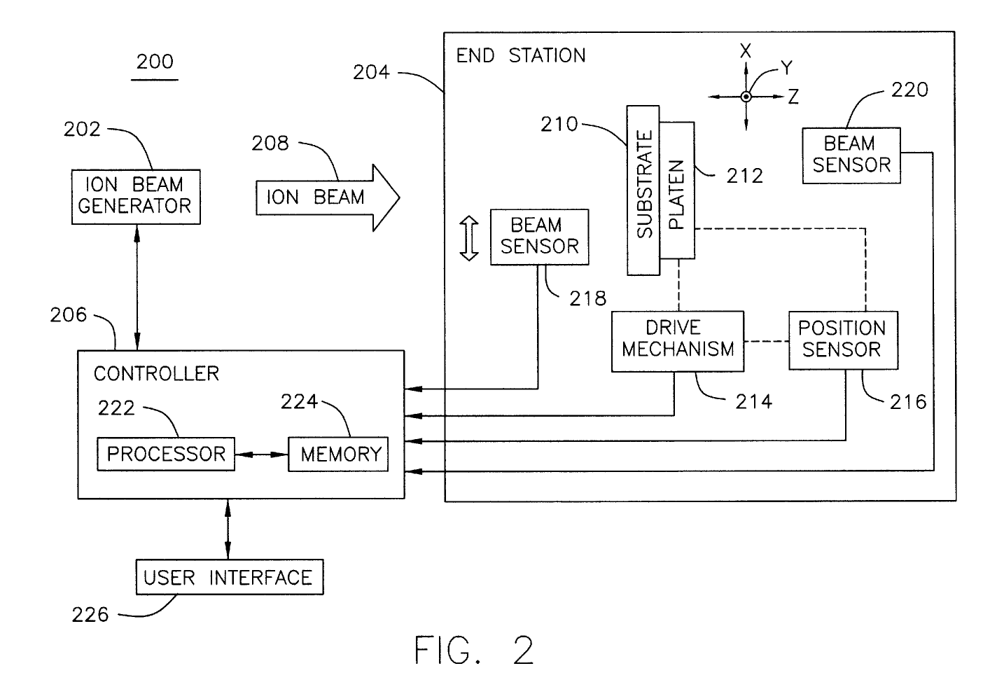

FIG. 2 shows a schematic block diagram of an ion implanter 200 that can be used in the forming of the thin-film solar cell according to one embodiment of this disclosure. The ion implanter 200 includes an ion beam generator 202, an end station 204, and a controller 206. The ion beam generator 202 generates an ion beam 208 and directs it towards a front surface of a substrate 210. The ion beam 208 is distributed over the front surface of the substrate 210 by beam movement, substrate movement, or by any combination thereof.

The ion beam generator 202 can include various types of components and systems to generate the ion beam 208 having desired characteristics. The ion beam 208 may be a spot beam or a ribbon beam. The spot beam may have an irregular cross-sectional shape that may be approximately circular in one instance. In one embodiment, the spot beam may be a fixed or stationary spot beam without a scanner. Alternatively, the spot beam may be scanned by a scanner for providing a scanned ion beam. The ribbon beam may have a large width/height aspect ratio and may be at least as wide as the substrate 210. The ion beam 208 can be any type of charged particle beam such as an energetic ion beam used to implant the substrate 210.

The end station 204 may support one or more substrates in the path of the ion beam 208 such that ions of the desired species are implanted into the substrate 210. The substrate 210 may be supported by a platen 212.

The end station 204 may include a drive system (not illustrated) that physically moves the substrate 210 to and from the platen 212 from holding areas. The end station 204 may also include a drive mechanism 114 that drives the platen 212 and hence the substrate 210 in a desired way. The drive mechanism 214 may include servo drive motors, screw drive mechanisms, mechanical linkages, and any other components as are known in the art to drive the substrate 210 when clamped to the platen 212.

The end station 204 may also include a position sensor 216, which may be further coupled to the drive mechanism 214, to provide a sensor signal representative of the position of the substrate 210 relative to the ion beam 208. Although illustrated as a separate component, the position sensor 216 may be part of other systems such as the drive mechanism 214. Furthermore, the position sensor 216 may be any type of position sensor known in the art such as a position-encoding device. The position signal from the position sensor 216 may be provided to the controller 206.

The end station 204 may also include various beam sensors to sense the beam current density of the ion beam at various locations such as a beam sensor 218 upstream from the substrate 210 and a beam sensor 220 downstream from the substrate. As used herein, “upstream” and “downstream” are referenced in the direction of ion beam transport or the Z direction as defined by the X-Y-Z coordinate system of FIG. 2. Each beam sensor 218, 220 may contain a plurality of beam current sensors such as Faraday cups arranged to sense a beam current density distribution in a particular direction. The beam sensors 218, 220 may be driven in the X direction and placed in the beam line as needed.

Those skilled in the art will recognize that the ion implanter 200 may have additional components not shown in FIG. 2. For example, upstream of the substrate 210 there may be an extraction electrode that receives the ion beam from the ion beam generator 202 and accelerates the positively charged ions that form the beam, an analyzer magnet that receives the ion beam after positively charged ions have been extracted from the ion beam generator and accelerates and filters unwanted species from the beam, a mass slit that further limits the selection of species from the beam, electrostatic lenses that shape and focus the ion beam, and deceleration stages to manipulate the energy of the ion beam. Within the end station 204 it is possible that there are other sensors such as a beam angle sensor, charging sensor, position sensor, temperature sensor, local gas pressure sensor, residual gas analyzer (RGA), optical emission spectroscopy (OES), ionized species sensors such as a time of flight (TOF) sensor that may measure respective parameters.

The controller 206 may receive input data and instructions from any variety of systems and components of the ion implanter 200 and provide output signals to control the components of the implanter. The controller 206 can be or include a general-purpose computer or network of general-purpose computers that may be programmed to perform desired input/output functions. The controller 206 may include a processor 222 and memory 224. The processor 222 may include one or more processors known in the art. Memory 224 may include one or more computer-readable medium providing program code or computer instructions for use by or in connection with a computer system or any instruction execution system. For the purposes of this description, a computer readable medium can be any apparatus that can contain, store, communicate, propagate, or transport the program for use by or in connection with the computer, instruction execution system, apparatus, or device. The computer-readable medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include a compact disk-read only memory (CD-ROM), a compact disk-read/write (CD-R/W) and a digital video disc (DVD).

The controller 206 can also include other electronic circuitry or components, such as application specific integrated circuits, other hardwired or programmable electronic devices, discrete element circuits, etc. The controller 206 may also include communication devices.

A user interface system 226 may include, but not be limited to, devices such as touch screens, keyboards, user pointing devices, displays, printers, etc., that allow a user to input commands, data and/or monitor the ion implanter 200 via the controller 206.

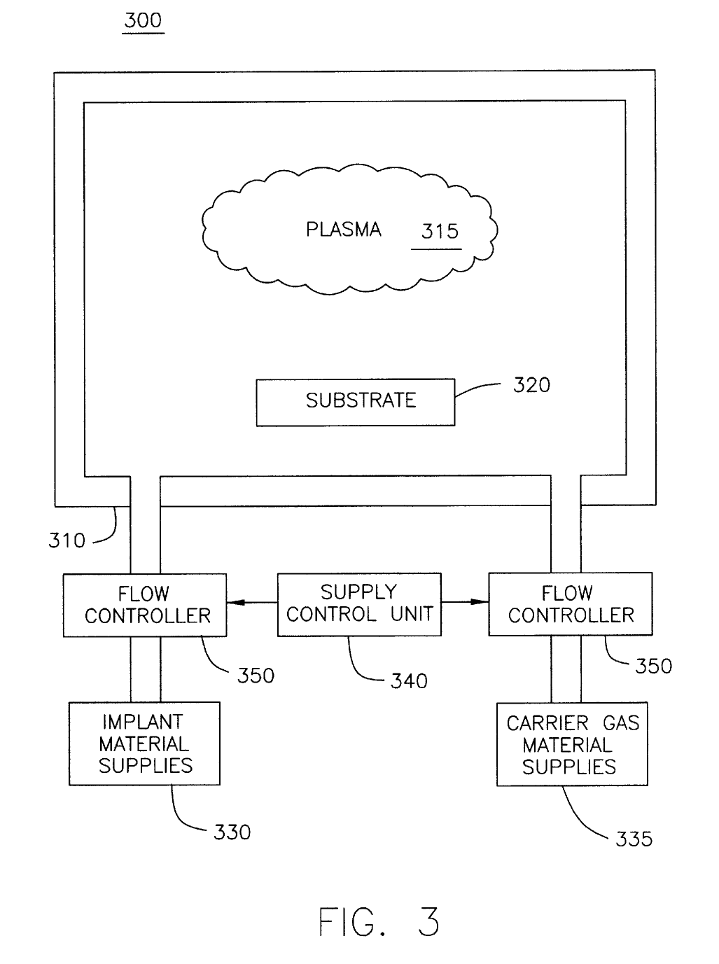

FIG. 3 shows a schematic block diagram of a plasma processing tool 300 that can be used in the forming of a thin-film solar cell according to one embodiment of this disclosure. The plasma processing tool 300 includes a vessel 310 associated with a chamber that can contain a plasma 315 and one or more substrates 320, which can be exposed to the plasma. The plasma processing tool 300 also includes one or more implant material supplies 330, one or more carrier gas material supplies 335, flow controllers 350, and one or more supply control units 340.

The supplies 330, 335 supply materials to the vessel 310 for formation and maintenance of a plasma. The flow controllers 350 regulate the flow of materials from the supplies 330, 335 to control, for example, the pressure of gaseous material delivered to the vessel 310. The supply control unit 340 is configured to control, for example, a mixture of carrier gas supplied to the vessel 310 by communicating with the flow controllers 350. The material supplies 330, 335, flow controllers 350, and control units 340 can be of any suitable kind, including those known to one having ordinary skill in the plasma processing arts.

In one mode of operation, the plasma processing tool 300 utilizes a pulsed plasma. A substrate 320 is placed on a conductive platen that functions as a cathode, and is located in the vessel 310. An ionizable gas containing, for example, an implant material, is introduced into the chamber, and a voltage pulse is applied between the platen and an anode to form a glow discharge plasma having a plasma sheath in the vicinity of the substrate. An applied voltage pulse can cause ions in the plasma to cross the plasma sheath and to be implanted into the substrate. A voltage applied between the substrate and the anode can be used to control the depth of implantation. The voltage can be ramped in a process to achieve a desirable depth profile. With a constant doping voltage, implant will have a tight depth profile. With a modulation of doping voltage, e.g., a ramp of doping voltage, implant can be distributed throughput the thin film, and can provide effective passivation to defect sites at variable depths.

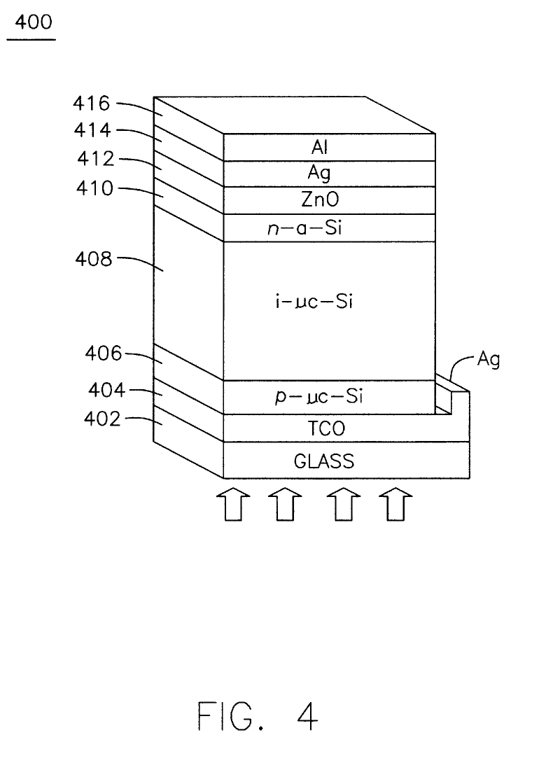

FIG. 4 is a cross-sectional diagram of a thin-film solar cell 400 that has been fabricated according to one embodiment of this disclosure. The thin-film solar cell 400 includes a glass substrate 402 having a TCO layer 404 deposited thereon. A thin-film solar cell is deposited on the TCO glass substrate. As shown in FIG. 4, the thin-film solar cell is a multi-layer thin-film silicon solar cell that includes p-i-n solar cells. In particular, a p microcrystalline silicon layer 406 is deposited on the TCO layer 404. An i microcrystalline silicon layer 408 is deposited on the p microcrystalline silicon layer 406. An n-amorphous silicon layer 410 is deposited on the i microcrystalline silicon layer 408.

On top of the thin-film solar cell is a capping layer. As shown in FIG. 4, the capping layer includes a zinc oxide (ZnO) layer 412 deposited over the n-amorphous silicon layer 410. A silver (Ag) layer 414 is deposited over the ZnO layer 412 and an aluminum (Al) layer 416 is deposited over the Ag layer 414.

The thin-film silicon solar cell 400 shown in FIG. 4 can be fabricated in the manner described with referenced to FIG. 1. In particular, the thin-film solar cell 400 can be fabricated with PECVD, light exposure, ion implantation, and the other aforementioned processing acts. Therefore, the thin-film silicon solar cell 400 can have improved cell efficiency by ion passivation with reference to the process without ion passivation steps.

It is apparent that there has been provided with this disclosure an approach that provides material modification in solar cell fabrication with ion doping. While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the invention.

What is claimed is:

1. A method of forming a thin-film solar cell, comprising:
providing a substrate;
depositing a thin-film layer on the substrate; and
exposing the thin-film layer to an ion flux to passivate a defect.

2. The method according to claim 1, wherein the substrate comprises glass.

3. The method according to claim 2, further comprising depositing a transport conductive oxide layer on the glass substrate prior to depositing the thin-film layer.

4. The method according to claim 1, wherein the thin-film layer comprises silicon.

5. The method according to claim 4, wherein the silicon comprises amorphous silicon or microcrystalline silicon.

6. The method according to claim 4, wherein the thin-film layer comprises a multi-layer of silicon.

7. The method according to claim 4, wherein the depositing of a thin-film layer comprises using plasma-enhanced chemical vapor deposition with materials selected from the group consisting of hydrogen and silane, deuterium and deuterated silane, deuterium and silane, and hydrogen and deuterated silane.

8. The method according to claim 1, wherein the ion flux contains ions selected from the group consisting of boron, phosphorous, hydrogen, and deuterium.

9. The method according to claim 1, wherein the exposing of the thin-film layer to an ion flux comprises generating the ion flux from one of a plasma, an ion beam or an electrolyte solution.

10. The method according to claim 1, wherein the ion flux energy is modulated during exposure.

11. The method according to claim 1, wherein the exposing of the thin-film layer to an ion flux occurs at a temperature that is less than about 300° C.

12. The method according to claim 1, further comprising depositing a capping layer over the thin-film structure after exposing the ion flux to the thin-film layer.

13. The method according to claim 1, further comprising exposing the thin-film layer to a light source prior to exposing the thin-film layer to the ion flux.

14. The method according to claim 13, wherein the light source is selected from the group consisting of a simulated sunlight source, an ultraviolet lamp and a laser beam.

15. A method of forming a thin-film solar cell, comprising:
providing a substrate;
depositing a thin-film silicon layer on the substrate;
exposing the thin-film silicon layer to a light source; and
implanting the thin-film silicon layer with an ion flux.

16. The method according to claim 15, wherein the implanted ion flux contains ions selected from the group consisting of boron, phosphorous, hydrogen, and deuterium.

17. The method according to claim 15, wherein the light source is selected from the group consisting of a simulated sunlight source, an ultraviolet lamp and a laser beam.

18. The method according to claim 15, wherein the implanting of the thin-film silicon layer with an ion flux comprises generating the ion flux from one of a plasma, an ion beam or an electrolyte solution.

19. The method according to claim 15, wherein the ion flux energy is modulated during exposure.

20. The method according to claim 15, wherein the implanting of the thin-film silicon layer with an ion flux occurs at a temperature that is less than about 300° C.

21. The method according to claim 15, further comprising capping the thin film silicon layer with a conductive material.

22. A method of forming a thin-film solar cell, comprising:
providing a substrate;
depositing a thin-film silicon layer on the substrate;
exposing the thin-film silicon layer to a light source;
implanting the thin-film silicon layer with an ion flux to passivate a defect, wherein the implanting of the thin-film silicon layer with an ion flux occurs at a temperature that is less than about 300° C. and wherein the ion flux contains ions selected from the group consisting of hydrogen and deuterium; and
capping the thin film silicon layer with a conductive material.

23. The method according to claim 22, wherein the light source is selected from the group consisting of a simulated sunlight source, an ultraviolet lamp and a laser beam.

24. The method according to claim 22, wherein the implanting of the thin-film silicon layer with an ion flux comprises generating the ion flux from one of a plasma, an ion beam or an electrolyte solution.

25. The method according to claim 24, wherein the ion flux energy is modulated during exposure.
